(19) United States
(12) Patent Application Publication
(10) Pub. No.: US 2013/0028446 A1
(43) Pub. Date: Jan. 31, 2013

(54) Orientation adjusting stereo audio output system and method for electrical devices

(71) Applicant: Paul Krzyzanowski, Flemington, NJ (US)

(72) Inventor: Paul Krzyzanowski, Flemington, NJ (US)

(73) Assignee: OPENPEAK INC., Boca Raton, FL (US)

(21) Appl. No.: 13/194,895

(22) Filed: Jul. 29, 2011

(51) Int. Cl. H03G 3/00

(52) U.S. Cl. 381/109

(57) ABSTRACT

Arrangements described herein relate to systems and methods for adjusting the audio output from an electrical device based on the orientation of the device to provide proper stereo audio output for more than one orientation of the device. The audio output system includes at least two speakers. The device includes an orientation sensor, which can be accelerometer, a gravity sensor, a gyroscope, a tilt sensor, an electronic compass, or combinations thereof. The audio output system can be operatively connected to the orientation sensor. Based on orientation data collected by the orientation sensor, output from the audio output system can be adjusted to provide audio output from opposing left and right regions of the device. Such adjustments can be implemented by the orientation sensor itself or by a switching device (such as a processor, digital logic gate or switching transistor) operatively positioned between the orientation sensor and the audio output system.

### FIELD

Embodiments relate in general to electrical devices and, more particularly, to electrical devices that provide stereo audio output.

### BACKGROUND

Some portable electrical devices, such as smart phones and tablet computers, are configured to provide stereo audio output. Stereo audio output is achieved by providing two speakers in opposite regions of the device. For instance, these two speakers are usually positioned on the left and right sides of the device or along the left and right ends of one edge of the device.

Some application software programs being executed on such electrical devices may generate video output that is best suited to a specific device orientation. For example, some games are designed for a portrait aspect ratio, while some others are best viewed in a landscape mode. However, tilting the device at a 90 degree angle can change the orientation of the speakers provided on the device. Thus, instead of providing audio from the left and the right, as intended, the speakers (and the sound emitted therefrom) may now be from the top and bottom of the device, destroying the left/right separation of audio channels. As a result, a user's enjoyment of the audio aspects of the device may be diminished.

Moreover, some portable electrical devices, like tablet computers and cell phones, contain orientation sensors and allow the visual output of applications and media to be presented properly regardless of the device's orientation. For example, a video can be displayed on the portable electrical device. The device can be placed into one of four possible orientations. A user can watch video on the device when the device is in any of four orientations because the orientation sensor ensures that the video is presented in the proper orientation. However, with a conventional two-speaker device, proper stereo output is provided in only one of these orientations.

Thus, there is a need for a system and method that can minimize such concerns.

### SUMMARY

In one respect, embodiments relate to an electrical device having an audio output system and an orientation sensor. The electrical device can be a cellular telephone, a smart phone, a personal digital assistant, a tablet computer, a laptop computer, a digital reader, a portable electrical device, a portable computing device, an entertainment device, a global positioning system device, a digital audio player, an e-book reader, a camera or a game console.

The audio output system includes two or more speakers. In one embodiment, one speaker can be located within a first region of the electrical device, and a second speaker can be located within a second region of the electrical device. The first region can be opposite the second region. In one embodiment, the audio output system can include three speakers.

The orientation sensor is configured to collect data regarding the orientation of the electrical device. The data regarding the orientation of the electrical device is used to adjust the output from the audio output system. In this way, stereo audio output can be provided for a plurality of orientations of the electrical device. In one embodiment, stereo audio output can be provided from opposing left and right regions of the electrical device for at least two different orientations of the electrical device.

The orientation sensor can be an accelerometer, a gravity sensor, a gyroscope, a tilt sensor, an electronic compass, a pressure sensor to detect the points at which the electrical device is being supported or combinations thereof. In one embodiment, the orientation sensor can be directly connected to the audio output system. In such case, the orientation sensor can be, for example, a mercury switch or a ball-bearing based position sensor. In another embodiment, the orientation sensor can be indirectly connected to the audio output system. In such case, a switching device can be operatively positioned between the orientation sensor and the audio output system. As an example, the switching device can be a processor. The processor can be configured to: determine the orientation of the electrical device based on orientation data collected by the orientation sensor, and adjust output from the audio output system based on the determined orientation. As another example, the switching device can be a switching transistor. As yet another example, the switching device can be a digital logic gate.

In another respect, embodiments are directed to an orientation adjusting stereo output method for an electrical device. The device has an audio output system including at least two speakers.

According to the method, data regarding the orientation of the electrical device is collected. The output from the audio output system is adjusted based on the data collected regarding the orientation of the electrical device. As a result, stereo audio output can be provided for a plurality of orientations of the electrical device. The method can further include determining whether the orientation of the electrical device has changed. If the orientation of the electrical device has changed, the audio output from the audio output system can be adjusted such that stereo audio output is provided from the electrical device to accommodate the new orientation.

In one embodiment, the adjusting can be performed by an orientation sensor. The orientation sensor can be an accelerometer, a gravity sensor, a gyroscope, a tilt sensor, an electronic compass, a pressure sensor to detect the points at which the electrical device is being supported, or combinations thereof. In another embodiment, the adjusting can be performed by a switching device operatively positioned between the orientation sensor and the audio output system. The switching device can be a processor, a switching transistor or a digital logic gate.

In one embodiment, the audio output system can have three speakers. In such case, the adjusting can include selecting at least two of the three speakers based on the determined orientation of the electrical device such that the selected speakers provide stereo audio output from the electrical device. Audio data can be output from the selected speakers.

In still another respect, embodiments are directed to an electrical device. The electrical device can be a cellular telephone, a smart phone, a personal digital assistant, a tablet computer, a laptop computer, a digital reader, a portable electrical device, a portable computing device, an entertainment device, a global positioning system device, a digital audio player, an e-book reader, a camera or a game console.

The electrical device includes an audio output system, which has at least three speakers: a first speaker, a second speaker and a third speaker. The device also includes an orientation sensor that is configured to collect data regarding the orientation of the electrical device. In one embodiment, the orientation sensor can be an accelerometer, a gravity sensor, a gyroscope, a tilt sensor, an electronic compass, or combinations thereof. Alternatively or in addition, the orientation sensor can be a pressure sensor to detect the points at which the electrical device is being supported.

Further, the device includes a processor that is operatively connected to the audio output system as well as to the orientation sensor. The processor is configured to (a) determine the orientation of the electrical device based on orientation data collected by the orientation sensor; (b) select at least two of the speakers based on the determined orientation of the electrical device; and (c) output audio data to the selected speakers. Thus, stereo audio output can be provided regardless of the orientation of the electrical device. The stereo audio output can be provided from opposing left and right regions of the electrical device.

The processor can be further configured to determine whether the orientation of the electrical device has changed based on orientation data collected by the orientation sensor. If the orientation of the electrical device has changed, the audio output from the audio output system can be adjusted such that stereo audio output is provided from the electrical device to accommodate the new orientation.

In one embodiment, the first speaker can be located within a first region of the electrical device. The second speaker being located within a second region of the electrical device. The first region can be opposite the second region. The third speaker can be located in the first region or in the second region of the device.

In yet another respect, embodiments are directed to an orientation adjusting stereo output method for an electrical device. The device has a processor, at least three speakers, and an orientation sensor. The processor is operatively connected to the at least three speakers as well as to the orientation sensor. The orientation sensor can be an accelerometer, a gravity sensor, a gyroscope, a tilt sensor, an electronic compass, or combinations thereof. Alternatively or in addition, the orientation sensor can be a pressure sensor to detect the points at which the electrical device is being supported.

According to the method, the orientation of the electrical device is determined based on orientation data collected by the orientation sensor. At least two of the three speakers are selected based on the determined orientation of the electrical device. The selected speakers can be on opposing left and right regions of the electrical device. Such selection can include selecting speakers that are located on opposing right and left regions of the electrical device. Audio data is output to the selected speakers. Thus, stereo audio output is provided regardless of the orientation of the device.

The method can also include determining whether the orientation of the electrical device has changed based on orientation data collected by the orientation sensor. If the orientation of the electrical device has changed, at least two of the three speakers can be selected based on the determined orientation of the electrical device to accommodate the new orientation. Thus, stereo audio output can be provided regardless of the orientation of the device.

### BRIEF DESCRIPTION OF THE DRAWINGS

FIG. 1 is a diagrammatic view of an electrical device.

FIG. 2 is a view of an electrical device having an audio output system including three speakers, wherein the electrical device is in a first orientation.

FIG. 3 is a view of the electrical device of FIG. 1 in a second orientation.

FIG. 4 is a view of the electrical device of FIG. 1 in a third orientation.

FIG. 5 is a view of the electrical device of FIG. 1 in a fourth orientation.

FIG. 6 is a diagrammatic view of an example of a direct switching system between an orientation sensor and an audio output system of the electrical device.

FIG. 7 is a diagrammatic view of an example of an indirect switching system between an orientation sensor and an audio output system of the electrical device.

FIG. 8 is a view of an electrical device having an audio output system including two speakers, wherein the electrical device is in a first orientation.

FIG. 9 is a view of the electrical device of FIG. 8 in a second orientation.

FIG. 10 is a view of the electrical device of FIG. 8 in a third orientation.

FIG. 11 is a view of the electrical device of FIG. 8 in a fourth orientation.

FIG. 12 is a view of an orientation adjusting stereo audio output method.

### DETAIL DESCRIPTION

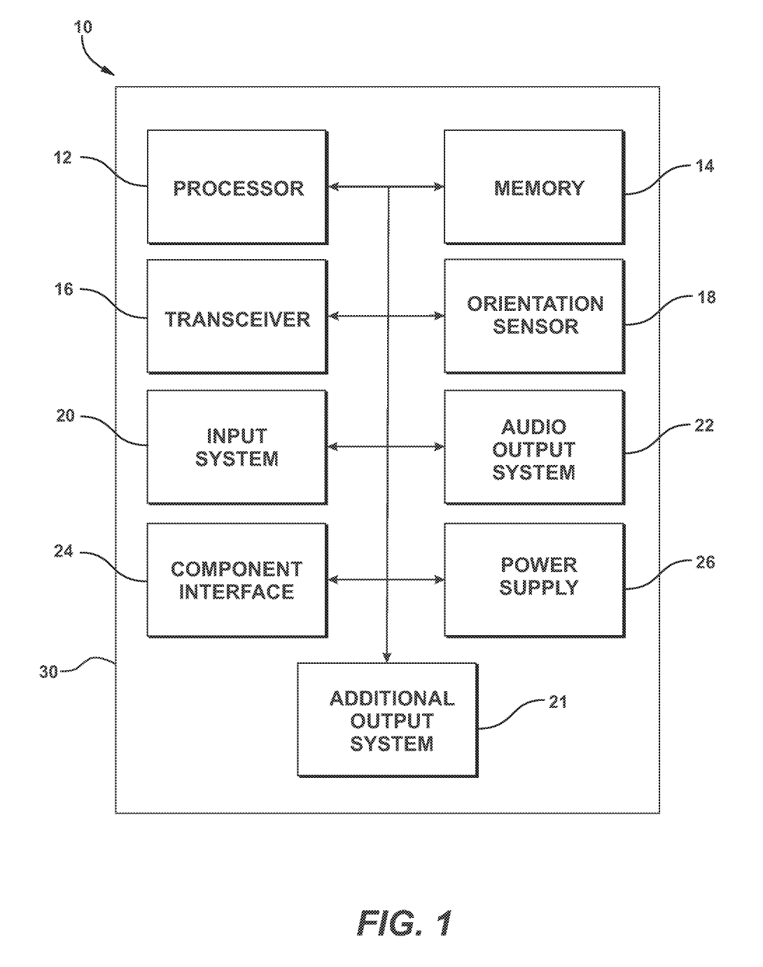

Arrangements described herein relate to orientation adjusting stereo output systems and methods for an electrical device. Detailed embodiments are disclosed herein; however, it is to be understood that the disclosed embodiments are intended only as exemplary. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Arrangements are shown in FIGS. 1-12, but the embodiments are not limited to the illustrated structure or application.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details.

Referring to FIG. 1, an exemplary electrical device 10 is shown. “Electrical device” means any device that is at least partially powered by electrical energy. The electrical device 10 can be any suitable device including, for example, a cellular telephone, a smart phone, a personal digital assistant (“PDA”), a tablet computer, a digital reader, a handheld device having wireless connection capability, a computer (e.g., a laptop), a portable electrical device, a portable computing device, an entertainment device (e.g., a music or video device, or a satellite radio), a global positioning system device, a digital audio player (e.g., MP3 player), an e-book reader, a camera or a game console. In some instances, the electrical device 10 can be configured to communicate via a wireless or wired medium. However, the electrical device 10 is not limited to devices with such capability, as the electrical device 10 may not be configured to communicate via a wireless or wired medium. Embodiments described herein can be implemented into any suitable electrical device, including any of those listed above. The electrical device 10 can include any suitable operating system.

Some of the various possible elements of the exemplary electrical device 10 shown in FIG. 1 will now be described. It will be understood that it is not necessary for an electrical device 10 to have all of the elements shown in FIG. 1 or described herein. The electrical device 10 can include a processor 12. The processor 12 may be implemented with one or more general-purpose and/or special-purpose processors. Examples of suitable processors 12 include microprocessors, microcontrollers, DSP processors, and other circuitry that can execute software. It should be noted that there may be instances in which the electrical device 10 does not include a processor 12 or the processor 12 is otherwise not involved in the adjusting of the audio output of the electrical device 10, as described in detail below. “Processor” means any component or group of components that are configured to execute any of the processes described herein.

The electrical device 10 can include memory 14 for storing various types of data. The memory 14 can include volatile and/or non-volatile memory. Examples of suitable memory 14 may include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The memory 14 can be operatively connected to the processor 12 for use thereby. The term “operatively connected,” as used throughout this description, can include direct or indirect connections, including connections without direct physical contact. There may be instances in which the electrical device 10 does not include memory 14 or the memory 14 is otherwise not involved in the adjusting of the audio output of the electrical device 10, as described in detail below.

The device 10 can include a transceiver 16. The transceiver 16 can be operatively connected to the processor 12 and/or the memory 14. In one embodiment, the transceiver 16 can be a wireless transceiver. Any suitable wireless transceiver can be used to wirelessly access a network or access point for the transmission and receipt of data. The transceiver 16 may use any one of a number of wireless technologies. Examples of suitable transceivers include a cellular transceiver, a broadband Internet transceiver, a local area network (LAN) transceiver, a wide area network (WAN) transceiver, a wireless local area network (WLAN) transceiver, a personal area network (PAN) transceiver, a body area network (BAN) transceiver, a WiFi transceiver, a WiMax transceiver, a Bluetooth transceiver, a 3G transceiver, a 4G transceiver, a ZigBee transceiver, a WirelessHART transceiver, a MiWi transceiver, an IEEE 802.11 transceiver, an IEEE 802.15.4 transceiver, or a Near Field Communication (NFC) transceiver, just to name a few possibilities. The transceiver 16 can include any wireless technology developed in the future. In other exemplary embodiments, the electrical device 10 may include one or more additional wireless transceivers (not shown) for accessing further wireless networks not accessible using the wireless transceiver 16. While much of the above discussion concerned a wireless transceiver, it will be understood that embodiments are not limited to wireless transceivers. Indeed, the transceiver 16 or an additional transceiver may be configured for wired network connections.

The electrical device 10 can collect information from which the orientation of the electrical device 10 can be determined. To that end, the electrical device 10 can include one or more orientation sensors 18. “Orientation sensor” means one or more devices, components and/or structures that collect data as to the orientation of an object. “Orientation” means the position of an object relative to a frame of reference. The orientation sensor 18 can be any suitable type of orientation detecting and/or determining hardware and/or software. For instance, the orientation sensor 18 can be an accelerometer, gravity sensor, a gyroscope, a tilt sensor, an electronic compass, or other suitable sensor, or combinations thereof. Further, the orientation sensor 18 may be a pressure sensor to detect the points at which the electrical device is being supported, such as the points at which the device is engaged by a user's hand and/or a surface upon which the electrical device 10 is resting.

The orientation sensor 18 can be operatively connected to the processor 12. As will be described below, the processor 12 can use information received from the orientation sensor 18 to adjust audio output of the electrical device 10 to maintain stereo audio output regardless of the orientation of the electrical device 10. However, it should be noted that, embodiments are not limited to such an arrangement. Indeed, alternative arrangements can include electrical devices 10 in which the switching of speaker outputs can be implemented in any suitable manner, including, for example, in an analog configuration or other forms that do not use computing elements.

The electrical device 10 can include an input system 20 for receiving input from a user. Any suitable input system 20 can be used, including, for example, a keypad, display, touch screen, button, joystick, mouse, microphone or combinations thereof. The electrical device 10 can include an output system 22 for presenting information to the user. The audio output system 22 can include an audio interface that can include one or more microphones, earphones and/or speakers. Additional features of the audio output system 22 will be described below. The electrical device 10 may also have additional output systems 21 for presenting information to the user. For instance, the additional output systems 21 may present visual information to the user and, in such case, can include a display. It should be noted that one or more of the items noted above may serve dual purposes such that the item is part of the input system 20 as well as the audio output system 22 and/or additional output systems 21.

The electrical device 10 may optionally include a component interface 24. Additional elements can be operatively connected to the component interface 24, including, for example, a universal serial bus (USB) interface or an audio-video capture system. The electrical device 10 may include a power supply 26. As is shown in FIG. 1, the processor 12, the memory 14, the transceiver 16, the orientation sensor 18, the input system 20, the audio output system 22, the other output system 21, the component interface 24 and/or the power supply 26 can be operatively connected in any suitable manner.

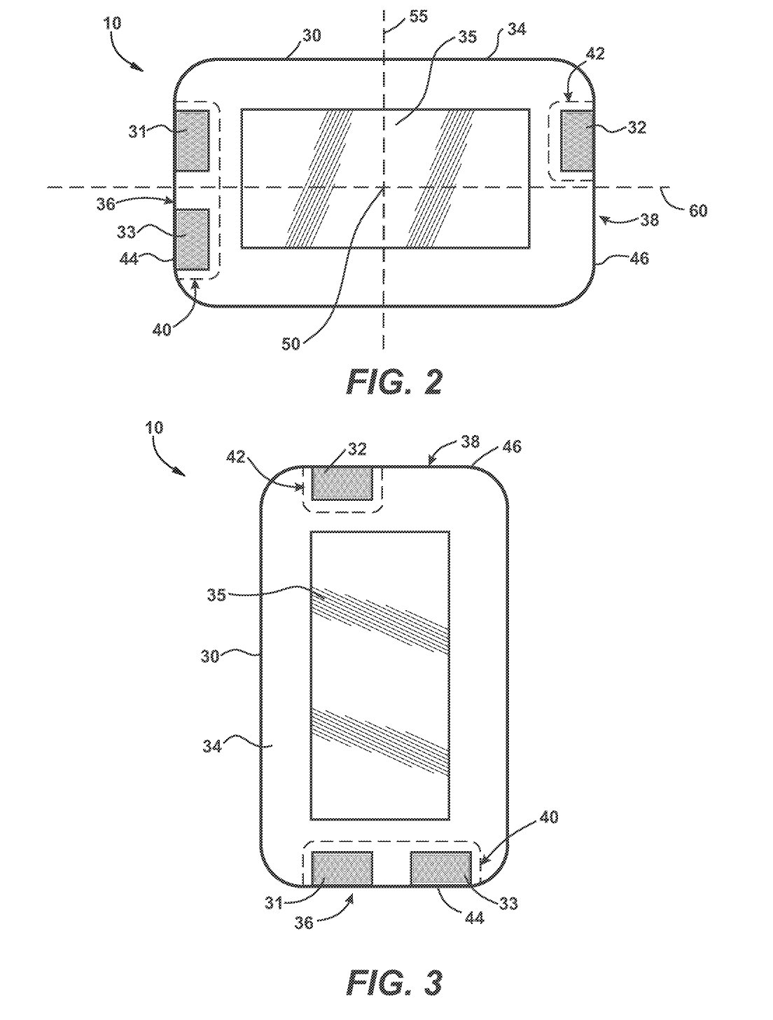

The electrical device 10 can have a housing 30, which can at least partially enclose one or more of the functional components of the electrical device 10, including the various components shown in FIG. 1. The housing 30 can be made out of any suitable material. The housing 30 can define at least a portion of the overall shape of the electrical device 10. The housing 30 can have any suitable shape, including a rectangular shape. While the housing 30/electrical device 10 is shown in FIGS. 2-5 as being substantially rectangular, it will be understood that embodiments are not limited to such a configuration. Indeed, it will be appreciated that embodiments described herein can be applied to housings and/or electrical devices with any suitable geometry, including, for example, those that are substantially circular, oval, parallelogram, trapezoidal, polygonal, triangular, or irregular just to name a few possibilities.

The audio output system 22 can comprise a plurality of speakers. Any suitable number of speakers can be provided. In one embodiment, the audio output system 22 can include at least three speakers, as is shown in FIGS. 2-5. There can be a first speaker 31, a second speaker 32 and a third speaker 33. A “speaker” is defined as one or more devices or components that produce sound in response to an audio signal input. Examples of speakers include, for example, electroacoustic transducers, sound chips, and sound cards. Each speaker 31, 32, 33 can have one or more audio output channels (not shown) operatively connected thereto. “Audio output channel” is defined as any suitable device, component or structure for carrying audio signals.

Data collected by the one or more orientation sensors 18 can be used to adjust the audio output of the electrical device 10 as appropriate to maintain stereo audio output. Such adjusting can be achieved directly or indirectly. Each of these possibilities will be considered in turn below.

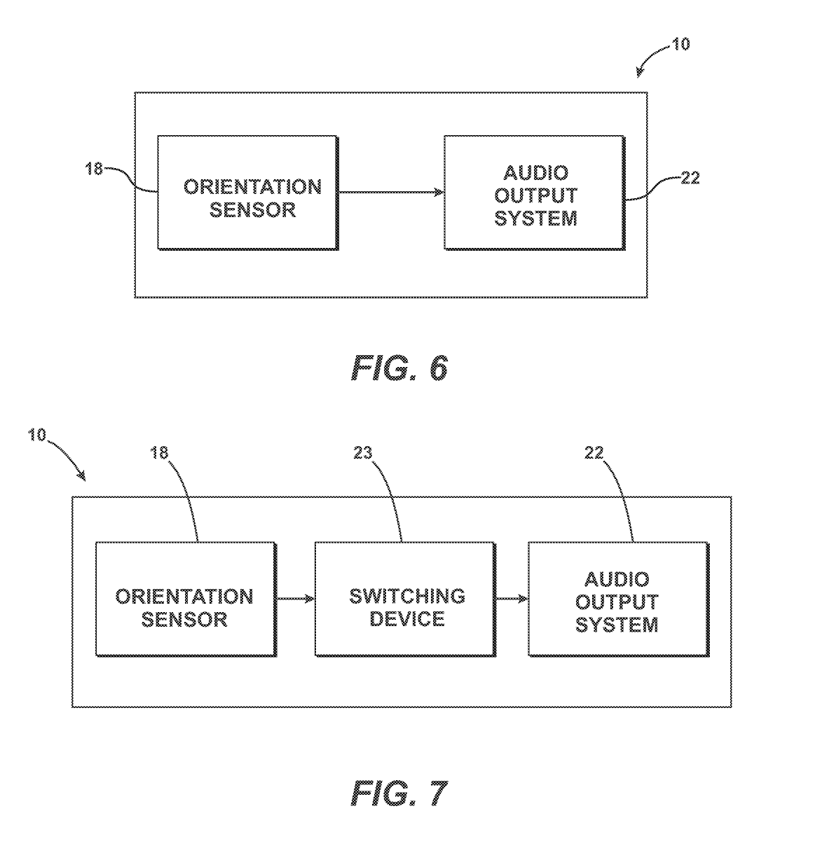

An example of an electrical device 10 having a direct switching system is shown in FIG. 6. In such case, the orientation sensor 18 can be configured so that the orientation of the electrical device 10 can cause contacts provided by the orientation sensors 18 to be made and/or broken. Thus, when the electrical device 10 is held in one position, certain contacts between the orientation sensors 18 and the audio output system 22 can be made and/or broken. When the electrical device 10 is held in another position, different combinations of contacts between the orientation sensors 18 and the audio output system 22 can be made and/or broken. In one embodiment, the orientation sensors 18 could be mercury switches. Alternatively or in addition, the orientation sensors 18 could include ball bearing-based position sensors. Again, these specific structures are provided merely as examples, and embodiments are not limited to these particular examples.

An example of an electrical device 10 having an indirect switching system is shown in FIG. 7. In such an arrangement, a switching device 23 can be operatively positioned between the orientation sensor 18 and the audio output system 22. In one embodiment, the switching device 23 can be switching transistors. The orientation sensors 18 can be operatively connected to the switching device 23 such that the switching device 23 is responsive to signals or inputs received from the orientation sensor 18. In another embodiment, the switching device 23 can be a digital logic gate, which can switch each input from the orientation sensor 18 to the desired output of the audio output system 22. The digital logic gate can be, for example, a NAND gate, a NOR gate, one or more other logic gates, and/or combinations thereof. The above-described system in which a processor 18 is operatively connected to control the speakers 31, 32, 33 is yet another example of an indirect switching system. Thus, the processor 18 is an example of a switching device. In such case, each of the speakers 31, 32, 33 can be operatively connected to the processor 12 by one or more audio output channels.

The electrical device 10 can be configured to implement the desired switching of audio output in any suitable manner, such as by having software executable thereon or accessible thereby. The switching of audio output can be performed in any of a number of ways. In one embodiment, the electrical device 10 can be configured to send audio signals over any audio output channel to any speaker. In such case, the electrical device 10 can be configured to select the appropriate audio output channels to associate with each speaker. Thus, the electrical device 10 can route audio signals over specific audio channels to specific speakers. Such switching can be implemented by the processor 18 or any other suitable component(s).

In an alternative arrangement, the electrical device 10 can be configured to send audio output to associated left and right output channels, as it conventionally would, but the electrical device 10 can be configured to switch the audio paths of the speakers in order to define what constitutes the left and right speakers. In effect, the electrical device can be operable to implement an a priori switching of audio outputs. In such case, the switching of the appropriate output channels can occur after the “left channel” audio output is sent to the left audio output channel and the “right channel” audio output is sent to the right audio output channel.

The speakers 31, 32, 33 can be arranged on the electrical device 10 in any suitable manner. In one embodiment, each of the speakers 31, 32, 33 can be provided on a major face, such as the front face 34, of the electrical device 10. In some instances, there may also be a display 35 on the front face 34 of the electrical device 10. The display can be any suitable type of display. Alternatively, the speakers 31, 32, 33 can be provided on opposing minor faces of the electrical device 10, such as opposing first and second edge sides 36, 38. Still alternatively, the speakers 31, 32, 33 may be provided on a combination of the major and minor faces of the electrical device 10.

The electrical device 10 can have a first region 40 and a second region 42. The first and second regions 40, 42 can be generally opposite to each other. For instance, when the electrical device 10 is rectangular, the first region 40 can include an area on the front face 34 of the electrical device 10 that is proximate to at least a portion of a first edge 44 of the electrical device 10. The first region 40 may include at least a portion of the first edge 44 of the electrical device 10, which may also include at least a portion of the first edge side 36. Alternatively, the first region 40 may be spaced from the first edge 44 of the electrical device 10.

Similarly, the second region 42 can include an area on the front face 34 of the electrical device 10 that is proximate to at least a portion of a second edge 46 of the electrical device 10. The second region 42 may include at least a portion of the second edge 46 of the electrical device 10, which may also include at least a portion of the second edge side 38. Alternatively, the second region 42 may be spaced from the second edge 46 of the electrical device 10.

The first and second regions 40, 42 can have any suitable size and/or shape. The first and second regions 40, 42 can be substantially identical to each other. Alternatively, the first and second regions 40, 42 can be different from each other in one or more respects, including, for example, in terms of size, shape and/or area. The first region 40 can be spaced from the second region 42. In one embodiment, the first and second regions 40, 42 can be separated by the display 35 or some other component or spacing. Alternatively, the first region 40 can be adjacent to the second region 42. The regions or speakers can be positioned anywhere on the electrical device to produce stereo audio output for a plurality of orientations of the device. “Stereo audio output” means an output that is achieved by using two or more independent audio channels through the configuration of two or more speakers.

It will be understood that the term “opposing,” as used throughout this description, means that the regions and/or speakers are provided on opposite sides of an axis and is not limited to the regions and/or the speakers being diametrically opposed to each other. In some embodiments, the regions and/or the speakers may be diametrically opposed, but embodiments are not limited to such an arrangement. As an example, the first and second speakers 31, 32 shown in FIG. 2 are located on opposite sides of an axis 55 and are diametrically opposed. Again, the arrangement of the speakers shown in FIGS. 2-5 and 8-11 are merely examples, and embodiments are not limited to these arrangements. Indeed, the speakers can be positioned virtually anywhere on the electrical device 10 as long as they are on opposite sides of an axis, including, for example, axis 55 or axis 60 (FIG. 2). Moreover, in some instances, the speakers may not be diametrically opposed and may even be offset from each other.

Referring to FIG. 2, two speakers can be provided in the first region 40, and one speaker can be provided in the second region 42. Of course, the opposite arrangement can be provided in which two speakers are provided in the second region 42 and one speaker is provided in the first region 40. As an example, the first speaker 31 and the third speaker 33 can be provided in the first region 40, and the second speaker 32 can be provided in the second region 42. As is shown in FIG. 2, the first and third speakers 31, 33 can be separated from the second speaker 32 by the display 35.

The first, second and third speakers 31, 32, 33 can be any suitable type of speaker. The speakers 31, 32, 33 can have any suitable conformation. For instance, the speakers 31, 32, 33 can be substantially rectangular or can have other suitable shape. The speakers 31, 32, 33 can be substantially identical to each other, or at least one of the speakers 31, 32, 33 can be different from the other speakers 31, 32, 33 in at least one respect, including, for example, size, shape, area, orientation and performance characteristics.

The speakers 31, 32, 33 can be arranged on the electrical device 10 in any suitable manner. For instance, the first and third speakers 31, 33 can be substantially aligned with each other. “Substantially aligned” means that if the outer profile of one of the speakers was moved toward the other speaker, then the outer profile of the moved speaker would eventually and at least partially overlap the other speaker. In one embodiment, a majority of the outer profile of the moved speaker would overlap the other speaker. In still another embodiment, the outer profile of the moved speaker would be located entirely within the other speaker, or the other speaker would be located entirely within the outer profile of the moved speaker, or the overlap between the outer profile of the moved speaker and the other speaker can be substantially identical. In some instances, the first and third speakers 31, 33 may be offset from each other.

The second speaker 32 can be provided in the second region 42. The second speaker 32 can be identical to the first and/or third speakers 31, 33. Alternatively, the second speaker 32 can be different from the first and/or third speakers 31, 33 in one or more respects, including, for example, in terms of size, shape, area, orientation and/or performance characteristics. The second speaker 32 can be placed in the second region 42 in any suitable manner. The second speaker 32 can be substantially aligned with one of the first or third speakers 31, 33. FIG. 2 shows an example of when the second speaker 32 is substantially aligned with the first speaker 31. However, in some instances, the second speaker 32 can be substantially aligned with the third speaker 32. The second speaker 32 can be substantially aligned with the first and third speakers 31, 33.

As noted above, the electrical device 10 can be equipped to determine the orientation of the device 10 in any suitable manner. Again, the orientation sensors 18 can directly adjust or switch the audio output of the device 10, or it can be done indirectly by another device that is operatively positioned therebetween. For this description, the following description will be directed to an indirect manner of audio adjusting or switching. In particular, the description will be directed to an embodiment in which a processor is used as a switching device to adjust the audio output of the device. However, it will be understood that this is merely an example and is not intended to be limiting.

The processor 12 can be configured to determine the orientation of the electrical device 10 based on data received from the orientation sensor 18. From such data, the processor 12 can determine which orientation the electrical device 10 is in. As an example, when the electrical device 10 has a rectangular shape, the electrical device 10 can have one of four possible orientations. FIG. 2 shows a first orientation. In such case, the first region 40 (along with the first and third speakers 31, 33) is located on a left hand side of the electrical device 10 relative to the user, and the second region 42 (along with the second speaker 32) is located on a right hand side of the electrical device 10.

FIG. 3 shows a second orientation. In such case, the electrical device 10 has been rotated substantially 90 degrees counterclockwise about axis 50 (which extends into and out of the page—see FIG. 2). In such case, the first region 40 (along with the first and third speakers 31, 33) is located on a lower side of the electrical device 10 relative to the user, and the second region 42 (along with the second speaker 32) is located on an upper side of the electrical device 10.

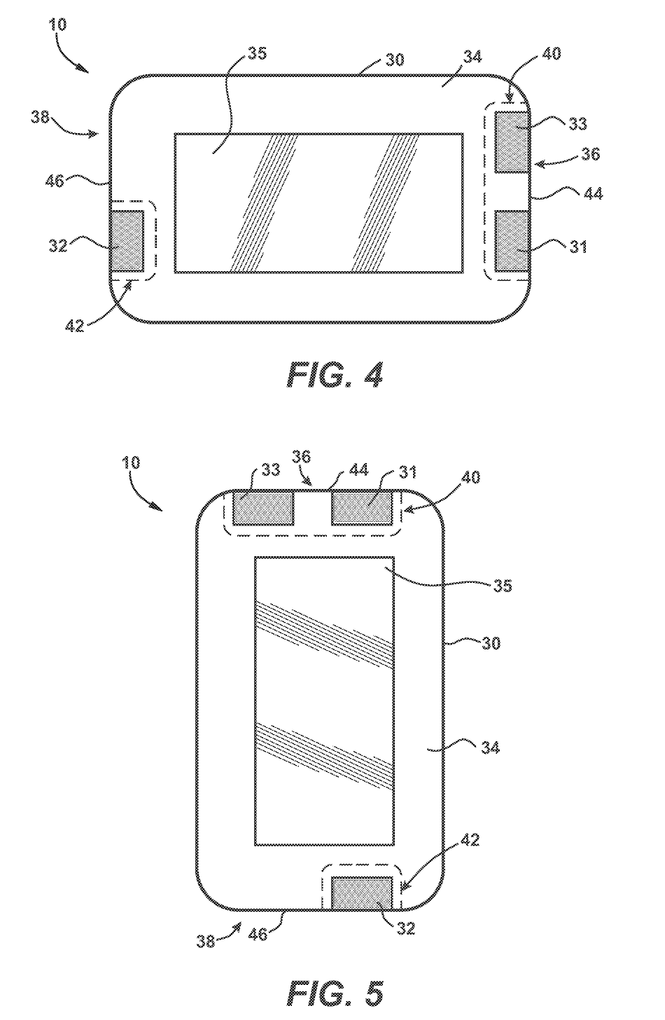

If the electrical device 10 is rotated another 90 degrees counterclockwise about the axis 50, then the device is in a third orientation, as is shown in FIG. 4. In the third orientation, the first region 40 (along with the first and third speakers 31, 33) is located on a right hand side of the electrical device 10 relative to the user, and the second region 42 (along with the second speaker 32) is located on a left hand side of the electrical device 10. If the electrical device 10 is rotated another 90 degrees counterclockwise about the axis 50, then the electrical device 10 is in a fourth orientation, as is shown in FIG. 5. In such case, the first region 40 (along with the first and third speakers 31, 33) is located on an upper side of the electrical device 10 relative to the user, and the second region 42 (along with the second speaker 32) is located on a lower side of the electrical device 10. There can be additional orientations, depending on the configuration of the electrical device 10.

Depending on the orientation, output to the speakers 31, 32, 33 may be selected to provide stereo audio output. In some instance, an appropriate subset of the speakers 31, 32, 33 can be selected to provide stereo audio output. For instance, when the electrical device 10 is in the first orientation, as is shown in FIG. 2, the first speaker 31 and the second speaker 32 may be selected. As will be appreciated, the first and second speakers 31, 32 are opposite each other in a left-right manner from the perspective of the user, thereby providing stereo audio output. When the electrical device 10 is in the second orientation, as is shown in FIG. 3, the first and third speakers 31, 33 can be selected. As will be appreciated, the first and third speakers 31, 33 are located opposite each other on left and right regions of the electrical device 10, thereby providing stereo audio output. When the electrical device 10 is in the third orientation, as is shown in FIG. 4, the second and first speakers 32, 31 can be selected. Again, the left to right opposition of the second and first speakers 32, 31 can ensure that the electrical device 10 provides stereo audio output. Lastly, when the electrical device 10 is in the fourth orientation, as is shown in FIG. 5, the third and first speakers 33, 31 can be selected to provide stereo audio output. If the electrical device 10 is held between two of the above orientations, then the electrical device 10 can be configured, such as by processor 12 or otherwise, to determine an appropriate audio output. It should be noted that the orientation sensor 18 and/or the processor 12 can also be configured to detect and account for movements of the device in other directions other than about axis 50, including, for example, movement about axes 55, 60 (see FIG. 2).

It should be noted that embodiments are not limited to having a subset of the speakers provide audio output. Indeed, it will be appreciated that audio output may be provided from all available speakers. For instance, there may be instances in which it is desired to provide audio output that consistently emanates from a particular region of the electrical device 10, such as the top or bottom regions of the device. In addition, some devices may use multiple speakers per audio output channel to separate amplification by frequency band, as is commonly done with tweeters and woofers. Finally, as with conventional multi-channel audio systems, low frequencies may be amplified through a single speaker (subwoofer) with no channel separation.

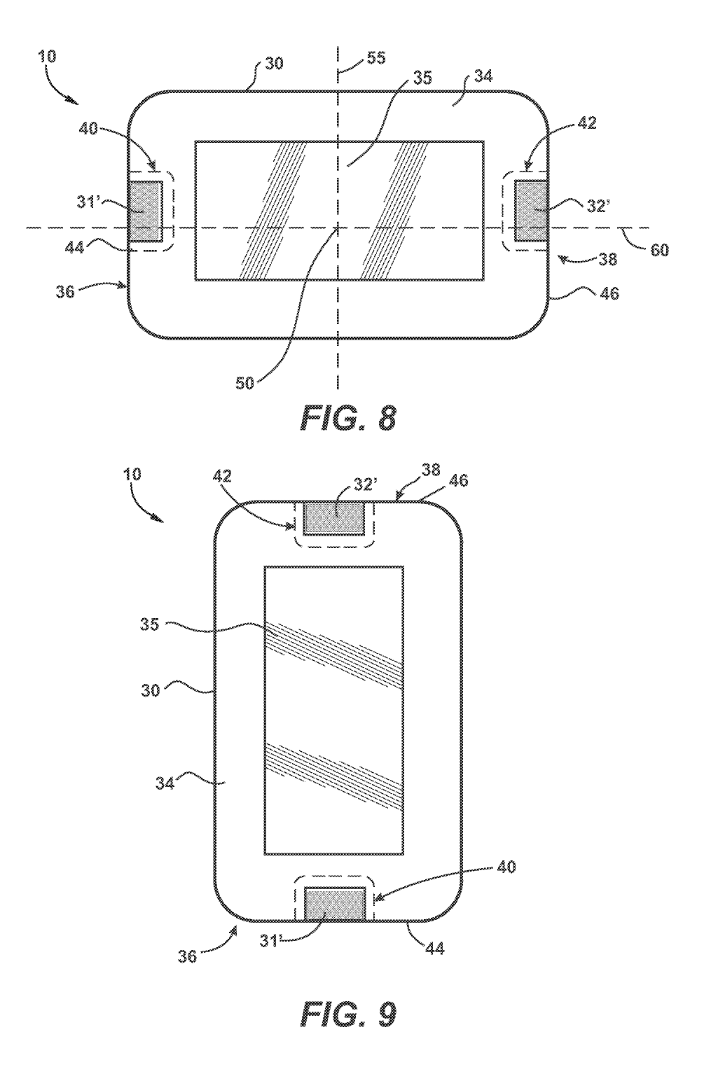

Further, while the above discussion was directed to an embodiment in which the audio output system 22 includes three speakers, it will be appreciated that embodiments can be applied to embodiments in which the output system having greater or fewer speakers. As an example, FIGS. 8-11 show an embodiment in which the electrical device includes two speakers. There can be a first speaker 31′ and a second speaker 32′. Each of the speakers 31′, 32′ can be operatively connected, directly or indirectly, to the orientation sensors 18 in any of the manners described above. The above discussion of the features, characteristics and arrangements of the speakers 31, 32, 33 applies equally to speakers 31′, 32′, with the first speaker 31′ generally corresponding to the first or third speakers 31, 33 and with the second speaker 32′ generally corresponding to the second speaker 32.

FIG. 8 shows a first orientation of the electrical device 10. In such case, the first region 40 (along with the first speaker 31′) is located on a left hand side of the electrical device 10 relative to the user, and the second region 42 (along with the second speaker 32′) is located on a right hand side of the electrical device 10.

FIG. 9 shows a second orientation. In such case, the electrical device 10 has been rotated substantially 90 degrees counterclockwise about axis 50 (which extends into and out of the page—see FIG. 8). In such case, the first region 40 (along with the first speaker 31′) is located on a lower side of the electrical device 10 relative to the user, and the second region 42 (along with the second speaker 32′) is located on an upper side of the electrical device 10.

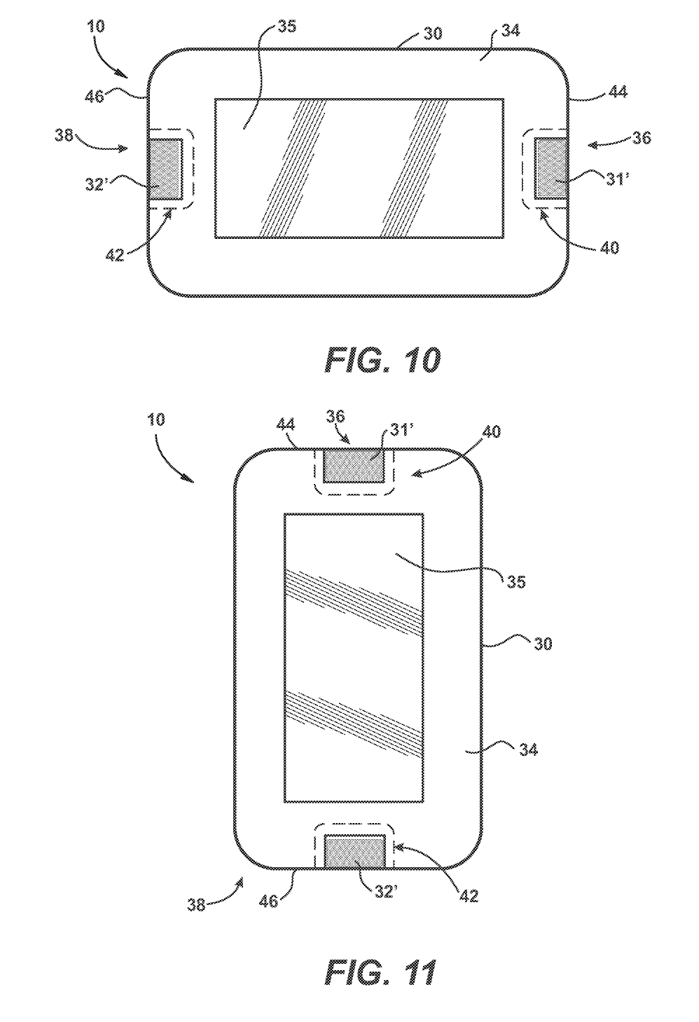

If the electrical device 10 is rotated another 90 degrees counterclockwise about the axis 50, then the device is in a third orientation, as is shown in FIG. 10. In the third orientation, the first region 40 (along with the first speaker 31′) is located on a right hand side of the electrical device 10 relative to the user, and the second region 42 (along with the second speaker 32′) is located on a left hand side of the electrical device 10.

If the electrical device 10 is rotated another 90 degrees counterclockwise about the axis 50, then the electrical device 10 is in a fourth orientation, as is shown in FIG. 11. In such case, the first region 40 (along with the first speaker 31′) is located on an upper side of the electrical device 10 relative to the user, and the second region 42 (along with the second speaker 32′) is located on a lower side of the electrical device 10. There can be additional orientations, depending on the configuration of the electrical device 10.

In this embodiment, audio output can be provided by the first and second speakers 31′, 32′ in all orientations. It will be appreciated, however, that only in the first and third orientations (FIGS. 8 and 10) can proper left-right stereo audio output be attained. Thus, when the electrical device 10 is in the first orientation (FIG. 8), audio from the left audio output channels can emanate from the first speaker 31′, and audio signals from the right audio output channels can emanate from the second speaker 32′. As a result, proper stereo output is achieved. When the electrical device 10 is in the third orientation (FIG. 10), audio from the left audio output channels can emanate from the second speaker 32′, and audio from the right audio output channels can emanate from the first speaker 31′. As noted above, there are various ways in which the proper left-right stereo audio output can be achieved.

Without implementing a system as described herein, the audio output of the electrical device 10, when held in the third orientation (FIG. 10), would not be proper, as audio signals from the left audio output channel would emanate from the right side of the device 10 and audio signals from the right audio output channel would emanate from the left side of the device 10. Further, it will be appreciated that systems and methods described herein may not be effective to provide proper audio output when the device is held in the second and fourth orientations (FIGS. 9 and 11), as the speakers 31′, 32′ are no longer positioned on the right and left sides of the device relative to the user. However, audio output can still be provided in each of these orientations. By using systems and methods described herein, proper stereo audio output can be provided in at least the first and third orientations (FIGS. 8 and 10).

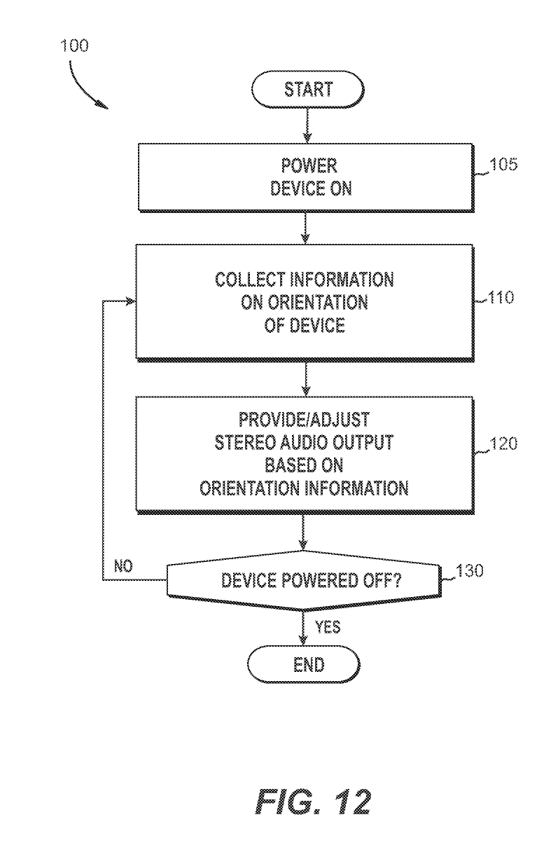

Now that the various components of the system have been described, one manner of the operation of the system will now be presented. Referring to FIG. 12, an orientation adjusting stereo audio output method 100 is shown. Various possible steps of method 100 will now be described. The method 100 illustrated in FIG. 12 may be applicable to the embodiments described above in relation to FIGS. 1-11, but it is understood that the method 100 can be carried out with other suitable systems and arrangements. Moreover, the method 100 may include other steps that are not shown here, and in fact, the method 100 is not limited to including every step shown in FIG. 12. The steps that are illustrated here as part of the method 100 are not limited to this particular chronological order, either. Indeed, some of the steps may be performed in a different order than what is shown and/or at least some of the steps shown can occur simultaneously.

In step 105, the electrical device 10 is powered on. In step 110, information on the orientation of the electrical device 10 can be collected. To that end, orientation data can be detected by the orientation sensor 18. With such information, audio output from the electrical device 10 can be adjusted at step 120 to ensure proper stereo audio output is provided. Such adjustment can be achieved in any suitable manner, including any of the ways described herein. Again, the orientation sensor 18 may be operatively connected to directly adjust the audio output from the speakers. Alternatively, the orientation sensor 18 may be operatively connected to indirectly adjust the audio output from the speakers, such as by a switching device or other device operatively positioned therebetween. For instance, the orientation data can be analyzed by the processor 12 or by another processor or component of the electrical device 10.

When three or more speakers are provided, audio output to the speakers can be selected, by the processor 12 or otherwise, to provide appropriate stereo audio output based on the orientation of the electrical device 10. Some of the possible speaker combinations are described above. It will be appreciated that the left-right audio output from the audio output system 22 can be maintained for the various orientations of the electrical device 10.

At decision block 130, it can be determined whether the device is powered off. If the electrical device 10 is off, then the method 100 can end. If the electrical device 10 is powered on, then the method 100 may continuously, periodically or randomly return to step 110 to determine the orientation of the electrical device 10, as the position of the electrical device 10 may have changed. The method 100 can continue as described above.

It will be appreciated that embodiments described herein can ensure that stereo audio output is delivered to the user, regardless of the orientation of the electrical device 10. While a user may choose to hold the electrical device 10 in a particular orientation depending on the use at hand, the audio output of the electrical device 10 can be matched appropriately to the device's orientation. As a result, it will be appreciated that the user's enjoyment of at least the audio aspects of the electrical device 10 can be maximized.

The flowcharts and block diagrams in the figures illustrate the architecture, functionality, and operation of possible implementations of systems, methods and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or other apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

The terms “computer program,” “software,” “application,” variants and/or combinations thereof, in the present context, mean any expression, in any language, code or notation, of a set of instructions intended to cause a system having an information processing capability to perform a particular function either directly or after either or both of the following: a) conversion to another language, code or notation; b) reproduction in a different material form. For example, an application can include, but is not limited to, a script, a subroutine, a function, a procedure, an object method, an object implementation, an executable application, an applet, a servlet, a MIDlet, a source code, an object code, a shared library/dynamic load library and/or other sequence of instructions designed for execution on a processing system.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e. open language).

Aspects herein can be embodied in other forms without departing from the spirit or essential attributes thereof. Accordingly, reference should be made to the following claims, rather than to the foregoing specification, as indicating the scope of the invention.

What is claimed is:

1. An electrical device comprising:
an audio output system having at least two speakers; and
an orientation sensor configured to collect data regarding the orientation of the electrical device, wherein the data regarding the orientation of the electrical device is used to adjust the output from the audio output system, whereby stereo audio output is provided for a plurality of orientations of the electrical device.

2. The electrical device of claim 1, wherein the orientation sensor is directly connected to the audio output system.

3. The electrical device of claim 2, wherein the orientation sensor is a mercury switch or a ball-bearing based position sensor.

4. The electrical device of claim 1, wherein the orientation sensor is indirectly connected to the audio output system.

5. The electrical device of claim 4, further including a switching device operatively positioned between the orientation sensor and the audio output system.

6. The electrical device of claim 5, wherein the switching device is a processor, wherein the processor is configured to:
determine the orientation of the electrical device based on orientation data collected by the orientation sensor; and
adjust output from the audio output system based on the determined orientation.

7. The electrical device of claim 5, wherein the switching device is a switching transistor.

8. The electrical device of claim 5, wherein the switching device is a digital logic gate.

9. The electrical device of claim 1, wherein the orientation sensor is an accelerometer, a gravity sensor, a gyroscope, a tilt sensor, an electronic compass, a pressure sensor to detect the points at which the electrical device is being supported or combinations thereof.

10. The electrical device of claim 1, wherein the electrical device is a cellular telephone, a smart phone, a personal digital assistant, a tablet computer, a laptop computer, a digital reader, a portable electrical device, a portable computing device, an entertainment device, a global positioning system device, a digital audio player, an e-book reader, a camera or a game console.

11. The electrical device of claim 1, wherein a first speaker is located within a first region of the electrical device and a second speaker is located within a second region of the electrical device, wherein the first region is opposite the second region.

12. The electrical device of claim 1, wherein audio output is provided from opposing left and right regions of the electrical device for at least two different orientations of the electrical device.

13. The electrical device of claim 1, wherein the audio output system includes three speakers.

14. An orientation adjusting stereo output method for an electrical device having an audio output system including at least two speakers, the method comprising:
collecting data regarding the orientation of the electrical device; and
adjusting the output from the audio output system based on the data collected regarding the orientation of the electrical device, whereby stereo audio output is provided for a plurality of orientations of the electrical device.

15. The method of claim 14, further including:
determining whether the orientation of the electrical device has changed; and
if the orientation of the electrical device has changed, adjusting the audio output from the audio output system such that stereo audio output is provided from the electrical device to accommodate the new orientation.

16. The method of claim 14, wherein the adjusting is performed by a switching device operatively positioned between the orientation sensor and the audio output system.

17. The method of claim 16, wherein the switching device is a processor, a switching transistor or a digital logic gate.

18. The method of claim 14, wherein the adjusting is performed by an orientation sensor.

19. The method of claim 18, wherein the orientation sensor is an accelerometer, a gravity sensor, a gyroscope, a tilt sensor, an electronic compass, a pressure sensor to detect the points at which the electrical device is being supported, or combinations thereof.

20. The method of claim 14, wherein the audio output system comprises three speakers.

21. The method of claim 20, wherein the adjusting includes:
selecting at least two of the three speakers based on the determined orientation of the electrical device such that the selected speakers are on opposing left and right positions of the electrical device; and
outputting audio data from the selected speakers.

22. An electrical device comprising:
an audio output system including a first speaker, a second speaker and a third speaker;
an orientation sensor configured to collect data regarding the orientation of the electrical device; and
a processor operatively connected to the audio output system and the orientation sensor, the processor being configured to:
determine the orientation of the electrical device based on orientation data collected by the orientation sensor;
select at least two of the speakers based on the determined orientation of the electrical device; and
output audio data to the selected speakers, whereby stereo audio output is provided to a user regardless of the orientation of the electrical device.

23. The electrical device of claim 22, wherein the orientation sensor is an accelerometer, a gravity sensor, a gyroscope, a tilt sensor, an electronic compass, or combinations thereof.

24. The electrical device of claim 22, wherein the orientation sensor is a pressure sensor to detect the points at which the electrical device is being supported.

25. The electrical device of claim 22, wherein the electrical device is a cellular telephone, a smart phone, a personal digital assistant, a tablet computer, a laptop computer, a digital reader, a portable electrical device, a portable computing device, an entertainment device, a global positioning system device, a digital audio player, an e-book reader, a camera or a game console.

26. The electrical device of claim 22, wherein the processor is further configured to:
determine whether the orientation of the electrical device has changed based on orientation data collected by the orientation sensor; and
if the orientation of the electrical device has changed, adjusting the audio output from the audio output system such that stereo audio output is provided from the electrical device to accommodate the new orientation.

27. The electrical device of claim 22, wherein stereo audio output is provided from opposing left and right regions of the electrical device.

28. The electrical device of claim 22, wherein the first speaker is located within a first region of the electrical device and the second speaker is located within a second region of the electrical device, wherein the first region is opposite the second region, and wherein the third speaker is located in one of the first region or the second region of the device.

29. An orientation adjusting stereo output method for an electrical device having a processor, at least three speakers, and an orientation sensor, the processor being operatively connected to the at least three speakers and the orientation sensor, the method comprising:
determining the orientation of the electrical device based on orientation data collected by the orientation sensor;
selecting at least two of the three speakers based on the determined orientation of the electrical device; and
outputting audio data to the selected speakers, whereby stereo audio output is provided regardless of the orientation of the device.

30. The method of claim 29, further including:
determining whether the orientation of the electrical device has changed based on orientation data collected by the orientation sensor; and
if the orientation of the electrical device has changed, selecting at least two of the three speakers based on the determined orientation of the electrical device to accommodate the new orientation, whereby stereo audio output is provided regardless of the orientation of the device.

31. The method of claim 29, wherein the selecting further includes selecting speakers that are located on opposing right and left regions of the electrical device.

32. The method of claim 29, wherein the orientation sensor is an accelerometer, a gravity sensor, a gyroscope, a tilt sensor, an electronic compass, or combinations thereof.

33. The method of claim 29, wherein the orientation sensor is a pressure sensor to detect the points at which the electrical device is being supported.

34. The method of claim 29, wherein the selected speakers are on opposing left and right regions of the electrical device.
